(19) United States
(12) Patent Application Publication
(10) Pub. No.: US 2011/0079766 A1
(43) Pub. Date: Apr. 7, 2011

(54) PROCESS FOR FABRICATING III-NITRIDE BASED NANOPYRAMID LEDS DIRECTLY ON A METALIZED SILICON SUBSTRATE

(76) Inventors: Isaac Harshman Wildeson, West Lafayette, IN (US); Timothy David Sands, West Lafayette, IN (US)

(21) Appl. No.: 12/896,073

(22) Filed: Oct. 1, 2010

Related U.S. Application Data
(60) Provisional application No. 61/247,786, filed on Oct. 1, 2009.

(51) Int. Cl. H01L 33/20; H01L 33/30

(52) U.S. Cl. 257/13; 438/29; 257/E33.005; 257/E33.023

(57) ABSTRACT

A nanopyramid LED and method for forming. The nanopyramid LED includes a silicon substrate, a III-nitride layer deposited thereon, a metal layer deposited thereon; and a nanopyramid LED grown in ohmic contact with the metal layer. The nanopyramid LED can be seeded on the III-nitride layer or metal layer. The metal layer can be a reflecting surface for the nanopyramid LED. The method for forming nanopyramid LEDs includes obtaining a silicon substrate, depositing a III-nitride layer thereon, depositing a metal layer thereon, depositing a dielectric growth layer thereon, etching a dielectric growth template in the growth layer, and growing III-nitride nanopyramid LEDs through the dielectric growth template in ohmic contact with the metal layer. The etching can be performed by focused ion beam etching. The etching can stop in the metal layer or III-nitride layer, so that the nanopyramid LEDs can seed off the metal layer or III-nitride layer, respectively.

### CROSS-REFERENCE TO RELATED APPLICATIONS

This application claims the benefit of U.S. Provisional Application Ser. No. 61/247,786, filed on Oct. 1, 2009, entitled “Process for Fabricating III-Nitride Based Nanopyramid LEDs Directly On a Metallized Silicon Substrate” which is incorporated herein by reference.

### GOVERNMENTAL SUPPORT INFORMATION

This invention was made with government support from the U.S. Department of Energy under grant/contract number DE-FC26-06NT42862; and from the U.S. Department of Defense under a NDSEG Fellowship. The Government has certain rights in the invention.

### BACKGROUND

The present invention relates to the fabrication of nanopyramid light emitting diodes (LEDs) on silicon substrates.

There is interest in the LED industry to move the growth of III-nitride LEDs to silicon substrates, which are available in low-cost, large diameter wafers. However, several qualities of silicon make this transition difficult. Some of the qualities that make this transition difficult are silicon's absorbance of visible light, and silicon's mismatch in both lattice parameter and coefficient of thermal expansion with the III-nitrides. Several researchers have developed processes for incorporating a reflective metallic layer between the silicon substrate and a light emitting film in order to resolve the problem of silicon absorbing light. One technique developed by a team including one of the inventors, Timothy Sands, is disclosed in U.S. patent application Ser. No. 12/424,517, entitled “Metalized Silicon Substrate for Indium Gallium Nitride Light-Emitting Diode,” which was filed on Apr. 15, 2009. That application discloses, inter alia, a zirconium nitride (ZrN)/aluminum nitride (AlN)/silicon (Si) substrate being used for epitaxial growth of III-nitride LED heterostructures in an organometallic vapor phase epitaxy reactor. ZrN is a better back contact/reflective layer than other proposed intermediate metallic layers, such as titanium nitride (TiN) or zirconium diboride (ZrB₂) due to its collective high reflectivity and ohmic contact nature with n-gallium nitride (n-GaN).

Silicon's mismatch in coefficient of thermal expansion with the III-nitrides results in cracking of the III-nitride layers if additional engineering is not employed. A common approach to eliminate the cracking of the III-nitride films is to compressively strain the film as it grows so that when it cools to room temperature the film is relaxed. This is typically done with intermediate AlN and AlGaN films when growing GaN on silicon. The disadvantage of this technique is that during growth the substrate is not flat, but instead is bowed, which leads to poor quality and non-uniformity of quantum well growth. An alternative way of eliminating the cracking of the III-nitride film without causing bow in the wafer during growth is to use patterned silicon substrates. By this technique, only small areas of the silicon substrate seed GaN, and these regions are small enough that the GaN films do not crack due to the stresses induced from the mismatch in the coefficient of thermal expansion. The disadvantage of this technique is that, as previously mentioned, the silicon substrate absorbs light and the light emitting films must be removed from the substrate in order to make an efficient device.

It would be desirable to have a method that eliminates the cracking of the light emitting III-nitride material, and that also incorporates a back contact/reflective layer to the LEDs on silicon.

### SUMMARY

A nanopyramid light-emitting diode is disclosed that includes a silicon substrate, a III-nitride layer deposited on the silicon substrate, a metal layer deposited on the III-nitride layer; and a III-nitride nanopyramid light-emitting diode grown in ohmic contact with the metal layer. The III-nitride nanopyramid light-emitting diode can be seeded on the III-nitride layer or the metal layer. The metal layer can be a reflecting surface for the nanopyramid light-emitting diode. The metal layer can be, for example, zirconium nitride or halfnium nitride. The III-nitride layer can be, for example, aluminum nitride or aluminum-gallium nitride. The III-nitride nanopyramid light-emitting diode can be a gallium nitride/indium-gallium nitride/gallium nitride nanopyramid.

A method for forming a nanopyramid light-emitting diode is disclosed where the method includes obtaining a silicon substrate, depositing a III-nitride layer on the silicon substrate, depositing a metal layer on the III-nitride layer, depositing a dielectric growth layer on the metal layer, etching a dielectric growth template in the dielectric growth layer, and growing III-nitride nanopyramid light emitting diodes through the dielectric growth template in ohmic contact to the metal layer. The method can include stripping the oxide layer from the silicon substrate prior to depositing a III-nitride layer on the silicon substrate: The III-nitride layer can be, for example, aluminum nitride or aluminum-gallium nitride. The metal layer can be, for example, zirconium nitride or halfnium nitride. The dielectric growth layer can be roughly 100 nm of silicon nitride. The etching of the dielectric growth template in the dielectric growth layer can be performed by focused ion beam etching, and the method can also include depositing a Au/Pd layer on the dielectric growth layer prior to etching, and cleaning after etching to remove the Au/Pd layer. The etching can be done to the dielectric growth layer, stopping in the metal layer so that the III-nitride nanopyramid light emitting diodes seed off the metal layer. The etching can be done to the dielectric growth layer and the metal layer, stopping in the III-nitride layer so that the III-nitride nanopyramid light emitting diodes seed off the III-nitride layer. The III-nitride nanopyramid light-emitting diodes can be gallium nitride/indium-gallium nitride/gallium nitride nanopyramids.

### BRIEF DESCRIPTION OF THE DRAWINGS

FIG. 1A illustrates III-nitride nanopyramid LEDs seeded directly off of a back contact/reflective layer (ZrN in this embodiment);

FIG. 1B illustrate III-nitride nanopyramid LEDs nucleating off of a III-nitride layer below a metal, reflective layer;

FIG. 2 is a transmission electron microscope image of GaN epitaxially grown on a ZrN/AlN/Si substrate by organometallic vapor phase epitaxy;

FIG. 3 is a transmission electron microscope cross-section of a GaN nanopyramid seeding off of AlN below ZrN; and

FIG. 4 is a transmission electron microscope cross-section of GaN nanopymamids grown through a dielectric template on a GaN/ZrN/AlN/Si substrate.

### DESCRIPTION OF EXEMPLARY EMBODIMENTS

For the purposes of promoting an understanding of the principles of the novel technology, reference will now be made to the embodiments described herein and illustrated in the drawings and specific language will be used to describe the same. It will nevertheless be understood that no limitation of the scope of the novel technology is thereby intended, such alterations and further modifications in the illustrated devices and methods, and such further applications of the principles of the novel technology as illustrated therein being contemplated as would normally occur to one skilled in the art to which the novel technology relates.

A process for fabricating low-cost, efficient light emitting diodes (LEDs) on silicon is disclosed. This process addresses the challenges of producing LEDs on silicon by the use of nanoheteroepitaxy and a back ohmic contact/reflective layer. III-nitride nanopyramid LEDs can be used to overcome the mismatch of the coefficient of thermal expansion between silicon and III-nitride materials. This technique allows for epitaxy on flat silicon wafers during high temperature growth. The technique does not require common strain engineering that results in bow of silicon wafers during growth, which leads to higher yields in production on silicon. This process can also provide a solution to the lattice mismatch between silicon and the III-nitrides, which typically results in high dislocation densities. The use of nanoheteroepitaxy provides a filter for dislocations originating from lattice mismatched interfaces, resulting in higher efficiency LEDs. This process can also address the challenge of silicon absorbing light by incorporating a reflective metal layer between the light emitting nanopyramids and the silicon substrate. This metal layer can also serve as an ohmic contact to nanorod bases of the nanopyramids LEDs, thus decreasing the resistance in the devices. This process can provide a practical approach for producing LEDs on silicon that results in material cost reductions. This process may also have applications outside of the area of solid-state lighting where III-nitride semiconductor nanorods grown directly on a metal layer are desired

III-nitride nanopyramids can be epitaxially grown directly on a metalized silicon substrate. This can provide a process for creating efficient, low-cost LEDs on silicon. The small dimensions of the nanopyramids allow relaxation of the strain that is induced by the coefficient of thermal expansion mismatch between silicon and the III-nitrides, thus allowing growth of LED structures on flat substrates, which can lead to greater yields. This can also decrease processing time and cost. Typically 3 μm of III-nitride growth is required for LED production. However, nanopyramid LEDs grown directly on a metal, or seeded from a III-nitride layer, such as AlN or AlGaN, directly below the metal layer, require less than 300 nm of growth. Moreover, nanopyramid LEDs can have qualities that are superior to thin film LEDs. For instance, by using dielectric templates to grow the III-nitride nanopyramids, complete dislocation filtering can be achieved, resulting in higher efficiency LEDs. When producing such small dimensioned LEDs, it is important to be able to make contact to the devices to connect them electrically to the outside. In this process the III-nitride nanopyramids can be grown in intimate contact with an ohmic contact metal. This ohmic contact can be achieved when the III-nitride nanopyramid is seeding off of the metal layer or when the III-nitride nanopyramid is seeding off of the III-nitride layer under the metal layer. The metal layer can also serve as a mirror that recovers light that normally would be absorbed by the silicon substrate. This processing technique can be advantageous in any application where epitaxially grown III-nitride nanorods are desired to be in contact with a metal layer on a low-cost substrate.

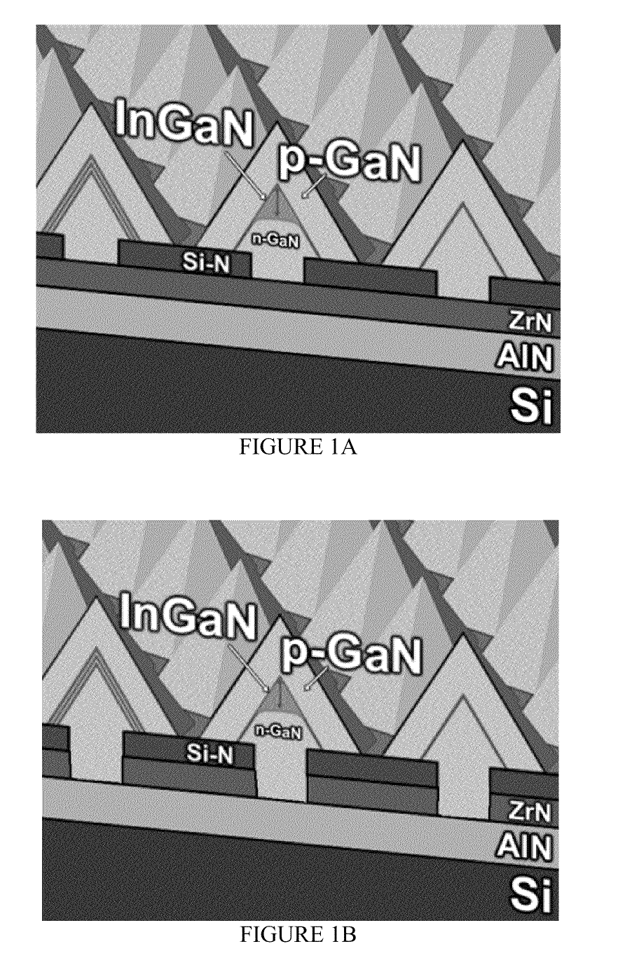

FIGS. 1A and 1B show examples of III-nitride nanopyramid LEDs grown on a metalized silicon substrate. FIG. 1A illustrates III-nitride nanopyramid LEDs seeded directly on top of a back contact, reflective metal layer. FIG. 1B illustrates III-nitride nanorods seeded off of a III-nitride layer directly below a reflective metal layer. For both examples illustrated in FIGS. 1A and 1B, the III-nitride nanorod base of the nanopyramids grows in intimate contact with the metal reflective layer, forming an ohmic contact. In these embodiments, zirconium nitride (ZrN) is used as the metal layer. The compositions illustrated in these figures depict only one embodiment of many alternatives. For example, the aluminum nitride (AlN) between the metal layer and silicon (Si) substrate could be replaced with aluminum-gallium nitride (AlGaN), and the ZrN metal layer could be replaced with hafnium nitride (HfN).

Note that in both FIGS. 1A and 1B, the metal layer serves as an ohmic contact and as a mirror reflecting light emission away from the absorbing silicon substrate. FIGS. 1A and 1B also illustrate the formation of hexagonal pyramids on top of each nanorod as it outgrows the dielectric template. These hexagonal pyramids are comprised of six semipolar {1-101} planes that possess about one tenth the polarization-induced electric fields in (In,Ga)N quantum wells as compared to those on the typical (0001) plane, and thus result in higher efficiency. The III-nitride nanopyramids grow with a hexagonal pyramid cap that allows efficient hexagonal close packing to maximize light output from the nanopyramid arrays.

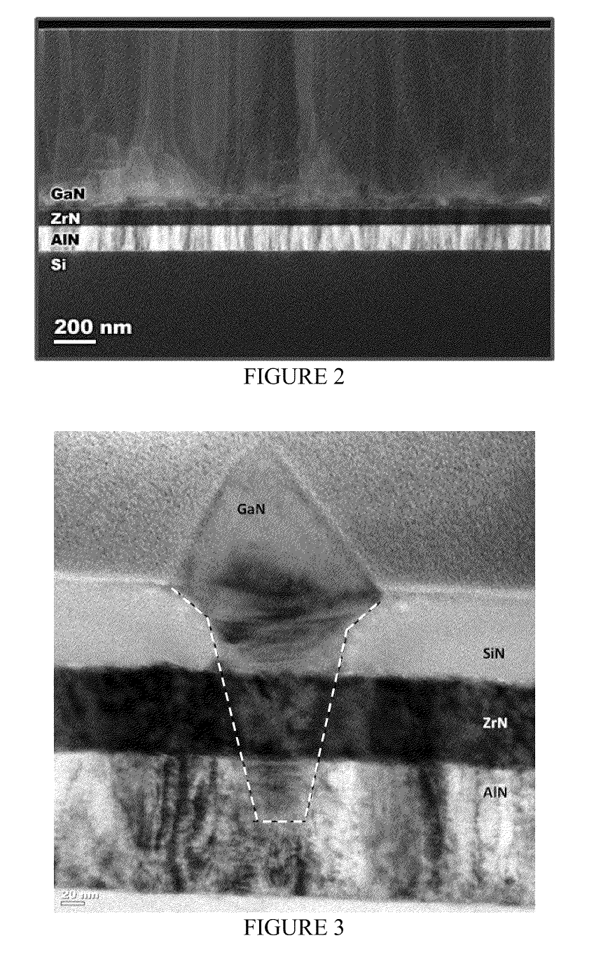

Other work confirmed the epitaxial growth of GaN on ZrN/AlN/Si substrates while using conventional organometallic vapor phase epitaxy. FIG. 2 is a transmission electron microscope image of GaN epitaxially grown on a ZrN/AlN/Si substrate by organometallic vapor phase epitaxy. On top of the ZrN film, ˜3 nm of AlN was deposited via sputtering.

The nanopyramid structures have several benefits over thin films in that they can be grown without extended defects and can have superior light extraction. In addition, the use of this technique on metalized silicon can reduce or eliminate the requirement for strain engineering to avoid cracking of the III-nitride light emitting film. The distinct nanopyramid LEDs are separated from one another and this allows for growth on a flat silicon wafer without cracking of the films.

Experiments have verified the fabrication of nanopyramid structures on metalized silicon as depicted in FIG. 1B where the nanorod bases seed off of the underlying III-nitride layer. FIG. 3 is a transmission electron microscope cross-section of a GaN nanopyramid seeding off of AlN below ZrN. The dashed line in FIG. 3 outlines the GaN nanopyramid. The nanorod base of the nanopyramid grows into contact with the metal layer (here ZrN) which creates an ohmic contact that can be used to electrically activate the device. The orientation of the GaN nanopyramids may not exactly aligned with that of the substrate. Current experiments, as depicted in FIG. 3, use focused ion beam etching to create holes in the dielectric growth mask for nanopyramids. In order to achieve nanopyramid nucleation directly off of the ZrN, a milder etching technique, such as reactive ion etch or inductively coupled plasma etch, can be employed so that the ZrN layer is not damaged during etching.

The starting substrates were phosphorous-doped n-type Si (111) substrates. The silicon wafers were stripped of their oxide and loaded into a reactive rf dc magnetron sputterer for deposition of AlN and ZrN. Details of a process for fabricating the ZrN/AlN/Si substrates can be found in M. H. Oliver, Appl. Phys. Lett. 93 (2008) 023109. Roughly 100 nm of silicon nitride (SiN) was then deposited on the ZrN/AlN/Si substrates to serve as a dielectric growth mask for the subsequent III-nitride selective area growth. Following the SiN deposition, ˜1 nm Au/Pd was deposited on the surface to minimize ion beam drifting during focused ion beam (FIB) etching of the growth template. Growth openings with diameters of roughly 100 nm were FIB etched through the SiN and possibly through the ZrN, depending on where the III-nitride nanorod nucleation was desired. Samples were then cleaned with a 30 sec dip in Aqua Regia followed by a 3 min rinse in deionized water to remove the Au/Pd and any residual Ga deposited by the ion beam. GaN nanopyramids were grown in an Aixtron 200HT organometallic vapor phase epitaxy reactor. Prior to deposition, samples were heated to 1030° C. in a mixture of 2:3 NH₃:H₂, and were held at this temperature for 3 minutes in an effort to recrystallize any surfaces damaged by the FIB etching. Growth of nanopyramids lasted a duration of 3 min at 1030° C. with hydrogen as the carrier gas. The V/III ratio during growth was 1427. Following the growth of the initial n-GaN nanopyramids, typical quantum well and p-GaN growth can be preformed to make working LED structures.

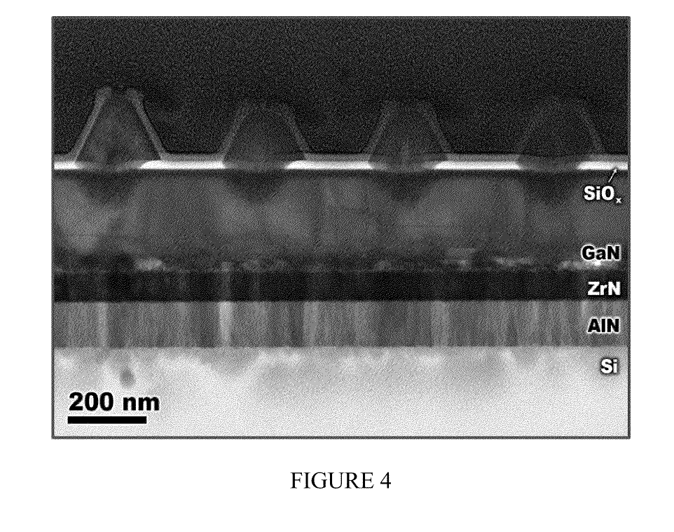

Some beneficial attributes of nanopyramid LEDs include: dislocation filtering, enhanced light extraction and semipolar facets for higher efficiency LEDs. In our previous work with nanopyramid LEDs, GaN nanopyramids were seeded directly off of a GaN film below a dielectric growth template. FIG. 4 is a transmission electron microscope cross-section of GaN nanopyramids grown through a dielectric template on a GaN/ZrN/AlN/Si substrate. In the current process, the GaN nanopyramids are seeded directly off of the metal layer or the underlying III-nitride layer.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains.

We claim:

1. A nanopyramid light-emitting diode comprising:
a silicon substrate;
a III-nitride layer deposited on the silicon substrate;
a metal layer deposited on the III-nitride layer; and
a III-nitride nanopyramid light-emitting diode grown in ohmic contact with the metal layer.

2. The nanopyramid light-emitting diode of claim 1, wherein the III-nitride nanopyramid light-emitting diode is seeded on the underlying III-nitride layer.

3. The nanopyramid light-emitting diode of claim 1, wherein the III-nitride nanopyramid light-emitting diode is seeded on the underlying metal layer.

4. The nanopyramid light-emitting diode of claim 1, wherein the metal layer is a reflecting surface.

5. The nanopyramid light-emitting diode of claim 1, wherein the metal layer is zirconium nitride.

6. The nanopyramid light-emitting diode of claim 5, wherein the III-nitride layer is aluminum nitride.

7. The nanopyramid light-emitting diode of claim 1, wherein the III-nitride layer is aluminum nitride.

8. The nanopyramid light-emitting diode of claim 1, wherein the metal layer is composed of zirconium nitride or halfnium nitride.

9. The nanopyramid light-emitting diode of claim 1, wherein the III-nitride layer is composed of aluminum nitride or aluminum-gallium nitride.

10. The nanopyramid light-emitting diode of claim 1, wherein the III-nitride nanopyramid light-emitting diode is a gallium nitride/indium-gallium nitride/gallium nitride nanopyramid.

11. A method for forming a nanopyramid light-emitting diode, the method comprising:
obtaining a silicon substrate;
depositing a III-nitride layer on the silicon substrate;
depositing a metal layer on the III-nitride layer;
depositing a dielectric growth layer on the metal layer;
etching a dielectric growth template in the dielectric growth layer;
growing III-nitride nanopyramid light emitting diodes through the dielectric growth template in ohmic contact with the metal layer.

12. The method of claim 11, further comprising stripping the oxide layer from the silicon substrate prior to depositing a III-nitride layer on the silicon substrate:

13. The method of claim 11, wherein the III-nitride layer is composed of aluminum nitride or aluminum-gallium nitride.

14. The method of claim 11, wherein the metal layer is composed of zirconium nitride or halfnium nitride.

15. The method of claim 11, wherein the dielectric growth layer is roughly 100 nm of silicon nitride.

16. The method of claim 11, wherein the etching of the dielectric growth template in the dielectric growth layer is performed by focused ion beam etching.

17. The method of claim 16, further comprising:
depositing a Au/Pd layer on the dielectric growth layer prior to etching; and
cleaning after etching to remove the Au/Pd layer.

18. The method of claim 11, wherein the etching is done to the dielectric growth layer, stopping in the metal layer, and the III-nitride nanopyramid light emitting diodes seed off the metal layer.

19. The method of claim 11, wherein the etching is done to the dielectric growth layer and the metal layer, stopping in the III-nitride layer, and the III-nitride nanopyramid light emitting diodes seed off the III-nitride layer.

20. The method of claim 11, wherein the III-nitride nanopyramid light-emitting diodes are gallium nitride/indium-gallium nitride/gallium nitride nanopyramids.
